(19) United States
(12) Patent Application Publication
(10) Pub. No.: US 2007/0004208 A1
(43) Pub. Date: Jan. 4, 2007

(54) Plasma etching apparatus and plasma etching method

(76) Inventor: Mitsuhiro Ohkuni, Nara-shi (JP)

Correspondence Address: MCDERMOTT WILL & EMERY LLP, 600 13TH STREET, N.W., WASHINGTON, DC, 20005-3096, US

(21) Appl. No.: 11/476,571

(22) Filed: Jun. 29, 2006

(30) Foreign Application Priority Data
Jun. 29, 2005 (JP) 2005-189261

(51) Int. Cl. C23F 1/00; H01L 21/302

(52) U.S. Cl. 438/689; 216/67; 156/345.48

(57) ABSTRACT

The plasma processing apparatus is provided with a chamber comprising a dielectric wall at the position opposing an object to be processed. A flat coil arranged exterior of the dielectric wall creates an induction magnetic field for generating the plasma. A plate-shaped electrode capable of functioning as a Faraday shield is arranged between the flat coil and the dielectric wall. And the apparatus provide with a heating unit configured to heat the periphery of the dielectric wall. The apparatus can prevent reaction products from adhering to the periphery of a dielectric wall by increasing the periphery temperature of the dielectric wall during an etching process, and suppressing the generation of particles.

### RELATED APPLICATIONS

This present application claims the benefit of patent application number 2005-189261, filed in Japan on Jun. 29, 2005, the subject matter of which is hereby incorporated herein by reference.

### BACKGROUND OF THE INVENTION

1. Field of the Invention

The present invention relates to a plasma etching apparatus and plasma etching method, and more particularly relates to a plasma etching apparatus and plasma etching method which can suppress the generation of particles during the etching process.

2. Description of the Related Art

In recent years, in accompaniment with high speed operation in semiconductor integrated circuits, the use of ferroelectric memory has been adopted in the nonvolatile memory of semiconductor integrated circuits. The ferroelectric memory generally is provided with construction which arranges an electroconductive film as an electrode above and below the ferroelectric film. As the material of the ferroelectric film, the material made of a strontium-bismuth-tantalum oxide (SBT), or the lead zirconate titanate (PZT) and the like is used. In addition, as the material of the electroconductive film used as an electrode (hereafter referred to as an electrode film), since the activity of the oxide is low and a ferroelectric film can be stably formed thereon, adoption may be made of metals such as platinum (Pt), iridium (Ir), and the like, or oxide materials such as IrO₂.

A plasma etching apparatus is used for the microfabrication processing of such types ferroelectric film or electrode film. Generally, these kinds of films are difficult to etch, and the etching rate is low. A schematic view of a plasma etching apparatus greatly used with this type of etching is shown in FIG. 10.

As shown in FIG. 10, the plasma etching apparatus is provided with a cylindrical chamber 1 which has the axis in the vertical direction. The chamber 1 is provided with a plate-shaped dielectric wall 2 as the upper wall, on the upper surface of which is provided a flat coil 3. In addition, at the opposing position to the dielectric wall 2, the chamber 1 is provide with a stage 6 on which is mounted a wafer to be the object of etching.

With the plasma etching apparatus composed in the manner described, when electric power from a high-frequency power source 5 is applied to the flat coil 3, the flat coil 3 generates a magnetic field where electrons have a nearly circular motion by making the axis of the chamber 1 to be the center of axis within the face perpendicular to the axial direction of the chamber 1. Owing to this, in a parallel face to the surface of the object to be etched, uniform plasma can be created, and the non-uniformity of the etching rate across the wafer is reduced.

In etching the electrode film, generally a halogen-based gas such as chlorine gas and the like is used as the etching gas. In this case, the etching is performed by reacting between the plasma of the halogen-based gas and the electrode film, and the reaction creates a metal halide. However, the metal halide created in the etching of the electrode film has a high boiling point, and is easily solidified when it reaches the inner surface of the chamber. Owing to this, it is difficult to exhaust in a gaseous form to the outside of the chamber, and the metal halide easily remains within the chamber 1. For example, relative to the fact that, at the time of plasma etching polysilicon or a silicon oxide film, the boiling point of the generated SiCl₄ is 58 degree C., and the boiling points of the metallic element chlorides described above are relatively high temperatures, as follows:
PtCl₂: 561 degree C.
PtCl₄: 370 degree C.
IrCl₃: 763 degree C.

In addition, as other electrode materials, utilization is also made of Al or Cu. However, the boiling points of the chlorides of these elements are relatively high temperatures, as follows:
AlCl₃: 183 degree C.
CuCl₃: 800 degree C.

In particular, with the plasma etching apparatus shown in FIG. 10, if the reaction product deposits on the dielectric wall 2 facing the stage 6, in the case of the reaction product exfoliate, they drop onto the stage 6, or in other words, they drop to the top of the wafer 7 during the etching process. The reaction product which has dropped onto the wafer 7 becomes a source of pattern defects in subsequent processes, with a remarkable reduction in the manufacturing yield of semiconductor integrated circuits.

Therefore, with the objective that the reaction product not adhere to the dielectric wall 2, a technology in which a electroconductive plate 13 to function as a Faraday shield is provided between the flat coil 3 and the dielectric wall 2 (hereafter referred to as a Faraday shield electrode 13) and direct current voltage or high-frequency electric power is applied to the Faraday shield electrode 13 is proposed (reference is made, for example, to International Publication No. WO96/25834, Japanese Unexamined Patent Publication No. 2001-345311, and Japanese Unexamined Patent Publication No. H10-275694).

According to this composition, by adjusting the electric potential of the Faraday shield electrode 13, the electric potential difference between the dielectric wall 2 and the plasma can be maintained at a specified value. Therefore, the amount of incident ions to the lower surface of the dielectric wall 2 can be adjusted. Owing to this, it makes possible to realize a chamber state in which the reaction product to be depositing on the lower surface of the dielectric wall 2 can be removed, and there is no etching of the dielectric wall 2, by means of adjusting the amount of ions incidental to the lower surface of the dielectric wall 2 from the plasma applying specified high-frequency electric power (or direct current electric potential) to the Faraday shield electrode 13 during etching of the object to be processed.

### SUMMARY OF THE INVENTION

However, in the case of forming a fine ferroelectric memory such as is applied in a 0.18 μm CMDS (Complementary Metal Oxide Semiconductor) process, multilayer film containing such as Pt, IrO₂, Ir and the like is used as electrode film since there is a need to suppress a degradation such as polarization fatigue. At the time of forming such electrode film, as shown, for example, in FIG. 11A, a Ir film 22, IrO₂ film 23 and Pt film 24 are formed in order from the bottom on a subterranean film 21 such as the ferroelectric film on which formed adhesive layer such as titanium or titanium nitride film. On the Pt film 24, a mask pattern 25 having an etching resistance against the halogen-based gas, such as silicon oxide film, titanium nitride film and the like, is formed using photolithography and the like. Also, the etching for the Pt film 24, IrO₂ film 23 and Ir film 22 by plasma etching process using the halogen-based gas as the etching gas and mask pattern 25 as the etching mask is performed, and then an electrode pattern as shown in FIG. 11B is formed. Moreover, if the mask pattern 25 is not an electroconductor, the mask pattern 25 is removed by etching and the like.

During the etching for the multilayer film, multiple types of reaction products such as PtCl₄, IrCl₃, and the like are created. Under conditions in which multiple types of the reaction products are created, the adhesion of the reaction products on the dielectric wall 2 tends to become non-uniform since each of the reaction products are not diffused in the same manner in the chamber 1. Owing to this, it is difficult to make the high-frequency electric power (or the direct current electric potential) applied to the Faraday shield electrode 13 set the conditions that remove the reaction products adhering to the dielectric wall 2 without etching the dielectric wall 2 across the entire surface of the dielectric wall 2.

On the other hand, since the periphery of the dielectric wall 2 is in close proximity to the side wall of the chamber 1, the possible angle at which ions are incidental is narrower than that of the center of the dielectric wall 2. Furthermore, the amount of the incident ions to the periphery of the dielectric wall 2 is smaller than the amount of the incident ions to the dielectric wall 2 in the center. Owing to this, the reaction products adhering to the periphery of the dielectric wall 2 make it difficult to perform etching through the operation of the Faraday shield electrode 13. And, in comparison to the center of the dielectric wall 2, the periphery of the dielectric wall 2 tends to easily deposit the reaction products. Also, during the etching process of materials which are difficult to etch, such as described above, since the reaction products easily adhere and deposit on the inner surface of the chamber 1, this tendency becomes stronger.

In this manner, in the case that the reaction products deposit on the periphery of the dielectric wall 2, particles are generated at the time that the reaction products exfoliate and make the manufacturing yield of the semiconductor integrated circuits reduce. In other words, during plasma etching process, the conventional technology which applies specified high-frequency electric power or direct current potential to the Faraday shield electrode 13 is insufficient technology from the perspective of removing the reaction products from the periphery of the dielectric wall 2 and suppressing the generation of particles.

The present invention has been proposed considering the conventional situation, and its objective is to provide a plasma etching apparatus and a plasma etching method that has the ability to prevent the adhesion of the reaction products across the entire dielectric wall which faces the object to be processed during the etching process even when performing etching process of a material which is difficult to etch.

The present invention employs the following means in order to accomplish the aforementioned object. A plasma etching apparatus relating to the present invention comprises a chamber which has a dielectric wall which transmits electromagnetic waves in a position opposing an object to be processed, a flat coil which generates a dialectic magnetic field in order to create the plasma arranged on the exterior of the chamber corresponding to the dielectric wall. Also, a plate-shaped electrode capable of functioning as a Faraday shield is arranged between the flat coil and the dielectric wall. In addition, a heating unit which heats the periphery of the dielectric wall is arranged.

The heating unit, for example, may be composed of a lamp which heats the periphery of the dielectric wall. In this case, in order to suppress heat discharged from the heated dielectric wall, it is desirable to provide a temperature retention film formed from SnO₂ and the like on the chamber inner surface side of the dielectric wall. In this instance, the lamp may be movably arranged along the periphery of the dielectric wall.

Moreover, the heating unit may also embed a heater in the dielectric wall. Furthermore, the heating unit may also be constructed by an absorber of high-frequency electric power arranged at least on the periphery of the dielectric wall.

In addition, the plate-shaped electrode may be embedded in the dielectric wall.

According to the present construction, during an etching process, it is possible to increase the temperature at the periphery of the dielectric wall. Therefore, during the etching process, adhesion of the reaction products on the periphery of the dielectric wall is prevented, enabling the suppression of particle generation.

On the other hand, the present invention is able to provide a plasma etching method from another perspective. In other words, with the plasma etching method relating to the present invention, plasma is created within the chamber by a dialectic magnetic field generated by the flat coil arranged outside of the chamber relative to the dielectric wall capable of transmitting electromagnetic waves provided in a position opposing an object to be processed. Also, the etching processing is performed under a conditions in which no etching of the dielectric wall ions incidental to the dielectric wall from the plasma, by means of applying electric potential to a plate-shaped electrode arranged between the dielectric wall and the flat coil. In addition, the periphery of the dielectric wall is heated during the etching process.

According to the plasma etching apparatus and plasma etching process relating to the present invention, it is possible to suppress the generation of particles since the adhesion of reaction products can be positively prevented on the dielectric wall opposing the object to be processed. Therefore, even with an etching process which forms a fine pattern, high manufacturing yield can be realized.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic view of the plasma etching apparatus of the first embodiment of the present invention.

FIG. 2 is a schematic top view of the plasma etching apparatus of the first embodiment of the present invention.

FIG. 3 is a drawing which shows the temperature dependency of the increased particle counts in the first embodiment of the present invention.

FIG. 4 is a schematic view of the plasma etching apparatus of the second embodiment of the present invention.

FIG. 5 is a schematic top view of a plasma etching apparatus of the second embodiment of the present invention.

FIG. 6 is a drawing that shows the temperature dependency of the increased particle counts in the second embodiment of the present invention.

FIG. 7 is a schematic view of a plasma etching apparatus of the third embodiment of the present invention.

FIG. 8 is a schematic top view of the plasma etching apparatus of the third embodiment of the present invention.

FIG. 9 is a schematic view which shows a variation example of the plasma etching apparatus of the first embodiment of the present invention.

FIG. 10 is a schematic view of a conventional plasma etching apparatus.

FIG. 11A and 11B are cross-sectional views of a multilayered electrode.

### DETAILED DESCRIPTION OF THE PREFERRED EMBODIMENTS

### First Embodiment

A detailed description of a plasma etching apparatus and plasma etching method relating to a first embodiment of the present invention is provided hereafter, with reference to the drawings.

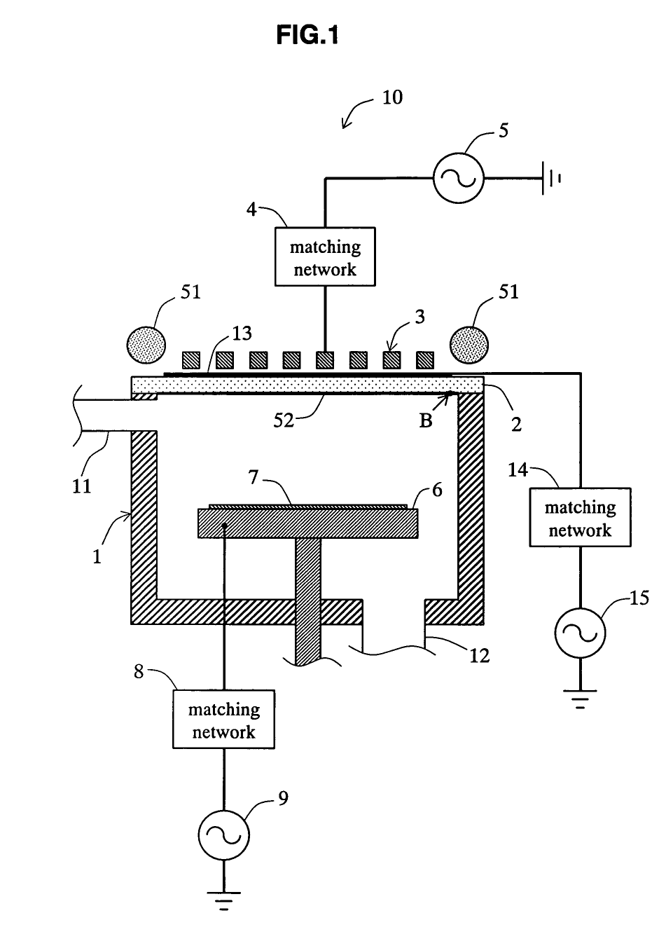

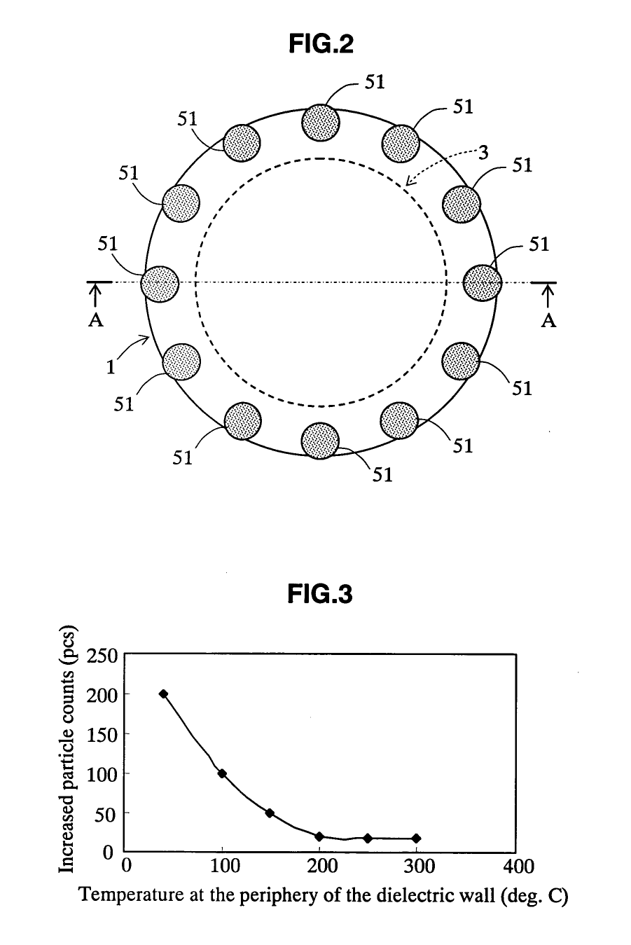

FIG. 1 is a schematic view showing the plasma etching apparatus relating to the present embodiment. Moreover, FIG. 2 is a schematic top view showing the plasma etching apparatus relating to the present embodiment. In addition, FIG. 1 is a cross-sectional view at the A-A line shown in FIG. 2. Furthermore, in FIG. 2, a flat coil is shown only its outer shape by the broken line.

As shown in FIG. 1 and FIG. 2, the plasma etching apparatus relating to the present embodiment is provided with a chamber 1 of nearly cylindrical shape having an axis in the vertical direction. The upper wall of the chamber 1 is constructed from, for instance, a plate-shaped dielectric wall 2 consisting of a dielectric material such as quarts. On the upper surface of the dielectric wall 2 is arranged a Faraday shield electrode 13. As explained above, the Faraday shield electrode 13 shifts the relative electric potential of the dielectric wall 2 relative to the plasma created in chamber 1, and has the function of adjusting the amount of ions incidental to the dielectric wall 2 created within the plasma.

Upper of the Faraday shield electrode 13 is provided a flat coil 3. The flat coil 3 is an electrically unified coil which is constructed in, for instance, a whorl-shape or nearly concentric circle shape. When high-frequency electric power is applied, then within a plane perpendicular to the axial direction of the chamber 1, a magnetic field is formed in which the electrons have a nearly circular motion by making the axis of the chamber 1 to be the center of axis.

In addition, so that the Faraday shield electrode 13 and the flat coil 3 are not electrically connected, the flat coil 3 is supported, for example, at a specified gap from the Faraday shield electrode 13 by means of an insulator provided on the upper surface of the dielectric wall 2.

Moreover, the plasma etching apparatus 10 is provided with a stage 6 on which a object to be processed 7 (hereafter referred to as a wafer 7) is mounted at a position opposing the dielectric wall 2 within the chamber 1. In addition, the wafer 7 mounted on the stage 6 is transported in and out of the chamber 1 via an unshown inlet/outlet port provided so as to be able to open and close at the sidewall, or bottom wall of the chamber 1.

Furthermore, the plasma etching apparatus 10 is provided with high-frequency power sources 5, 9, and 15 which independently apply high-frequency electric power on the flat coil 3, the stage 6 and the Faraday shield electrode 13 respectively. In addition, mating networks 4, 8 and 14 are respectively provided between the high-frequency power source 5 and the flat coil 3, the high-frequency power source 9 and the stage 6, and between the high-frequency power source 15 and the Faraday shield electrode 13. For example, matching networks 4 and 8 are adjusted to a matching state in which the loss of the high-frequency power applied by each of the high-frequency power sources 5 and 9 is minimized, corresponding to the change in the impedance of the object of high-frequency power application through the generation of plasma within the chamber 1. And the matching network 14 is adjusted to a state in which the chamber inner surface side of the dielectric wall 2 has a specified electric potential relative to the plasma by applying high-frequency power supplied from the high-frequency power source 15.

Also, a gas feed port 11, which introduces the process gas for creating the plasma, is provide to the upper part of the sidewall of the chamber 1, and a gas exhaust port 12, where the vacuum pump to maintain a specified pressure within the chamber 1, is provide to the lower part of the chamber 1.

The plasma etching apparatus 10 of the present embodiment, as shown in FIG. 1 and FIG. 2, is provided with a halogen lamp 51 as heating unit for heating the periphery of the dielectric wall 2. FIG. 2, upper of the dielectric wall 2, shows an example in which 12 lamps 51 are arranged at specified intervals along the periphery of the dielectric wall 2. The arrangement of the lamps 51 is not restricted, but is desirably arranged so that the overall periphery of the dielectric wall 2 has the same temperature. Moreover, so that heating the periphery of the dielectric wall 2 can be effectively executed, the Faraday shield electrode 13 is desirably arranged in a state in which the periphery of the dielectric wall 2 is not covered.

In this instance, lamps 51, in order to make the temperature distribution of the periphery of the dielectric wall 2 uniform, may be movably arranged along the periphery of the dielectric wall 2. For example, such construction may be realized by adopting a construction in which the lamps 51 is supported a rotatable support member making the axis of the chamber 1 to be the center axis in a plane parallel to the dielectric wall 2 in the construction shown FIG. 2. Also, the support member is rotated by a drive unit such as a motor and the like.

Furthermore, in the present embodiment, a temperature retention film 52 formed from SnO₂ and the like is formed on the lower surface (inner surface of chamber 1) of dielectric wall 2. The temperature retention film 52 suppresses the heat discharged from the dielectric wall 2 heated by light radiated from a lamp 51, and has the function of maintaining the temperature of the dielectric wall 2.

As indicated above, by heating the periphery of the dielectric wall 2 during the etching process, the solicitation and adhesion of the reaction products are suppressed at the chamber inner surface side of the periphery of the dielectric wall 2. In addition, even if the reaction products adhere to the dielectric wall 2, regasification of the adhering reaction products is performed by heating the periphery of the dielectric wall 2. Owing to this, according to the above construction, in the periphery of the dielectric wall 2, the adhesion of reaction products is suppressed by the heating of the lamps, and in the center of the dielectric wall 2, the adhesion of reaction products is suppressed by the operation of the Faraday shield electrode 13. As a result, during etching process, the adhesion of reaction products is prevented across the entire dielectric wall 2, suppressing the generation of particles.

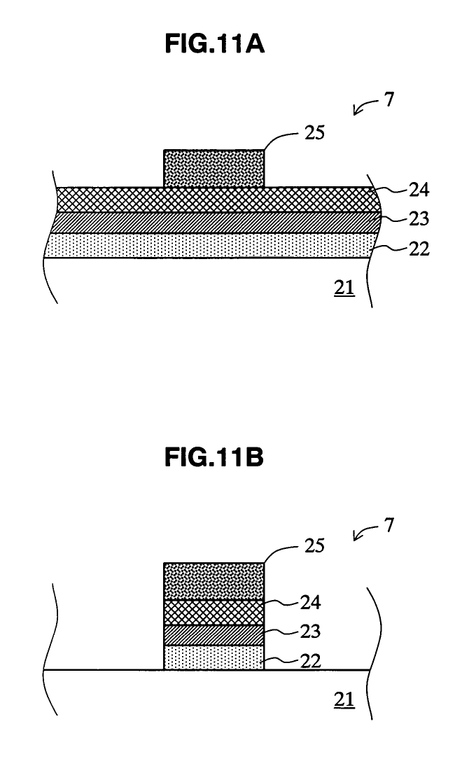

In addition, in the case where an electrode film which has the cross-sectional construction shown in FIG. 11A is etched, the temperature of the chamber inner surface side (arrow B in FIG. 1) at the periphery of the dielectric wall 2 is desirably maintained at 200 degree C. or greater, in particularly, at 250 degree C. or greater. At this time, the temperature of the in-chamber surface side at the center of the dielectric wall 2 is desirably maintained at from 150 degree C. to 200 degree C. by the heat transmission from the periphery. By so doing, in the periphery and the center of the dielectric wall 2, differences in the amount of adhesion of the reaction products caused by differences in the amount of indicate ions during etching can be removed through the temperature distribution of the dielectric wall 2, and the deposit of the reaction products can be suppressed across the entire dialectic wall 2.

FIG. 3, in the plasma etching apparatus 10 of the above composition, shows increased particle counts in the case of etching an electrode film which has the cross-sectional structure shown in FIG. 11A. In FIG. 3, the horizontal axis corresponds to the temperature at the chamber inner surface side of the periphery of the dielectric wall 2 (arrow B in FIG. 1), and the vertical axis corresponds to the increased particle counts. In this instance, the increased particle counts indicate a value which is the amount of particles on a wafer before an etching process subtracted from that on the wafer after the etching process. In addition, in this instance, only particles which have a granular diameter of 0.2 micrometers or greater are used to count the increased particle counts.

Moreover, etching the multilayered film can be performed by introducing a flow rate of 100 sccm of Cl₂ gas, and 250 sccm of O₂ gas as the etching gas, and at the same time, maintaining the pressure inside the chamber 1 at about 2.0 Pa. At this time, the high-frequency power source 5 applies the high-frequency power (at the frequency of 13.56 MHz) of 1500 W to the flat coil 3, the high-frequency power source 9 applies the high-frequency power (at the frequency of 13.56 MHz) of 200 W to the stage 6. In addition, the high-frequency power source 15 applies the high-frequency power (at the frequency: 12.56 MHz) of 300 W to the Faraday shield electrode 13. And then, the temperature of the stage 6 is maintained at about 50 degree C. by an unshown heater housed within the stage 6.

As shown in FIG. 3, in the case where heating by the lamps 51 is not performed (where the periphery temperature of the dielectric wall is 25 degree C.), relative to the fact that the increased particle counts is about 200 pcs, in the case of heating the periphery of the dialectic wall 2 to 200 degree C. or greater by means of the lamps 51 heating, the increased particle counts is reduced to about 20 pcs needed in generally semiconductor fabrication process.

As explained above, in the present embodiment, in the center of the dielectric wall 2, the adhesion of reaction products can be suppressed by the operation of the Faraday shield electrode 13 during the etching process, and in the periphery of the dielectric wall 2, the adhesion of the reaction products can be suppressed by heating the periphery temperature maintaining at 200 degree C. or greater. Therefore, the adhesion of reaction products can be suppressed across the entire surface of the dielectric wall 2. Owing to this, the plasma etching process can be stably accomplished without reducing the manufacturing yield.

### Second Embodiment

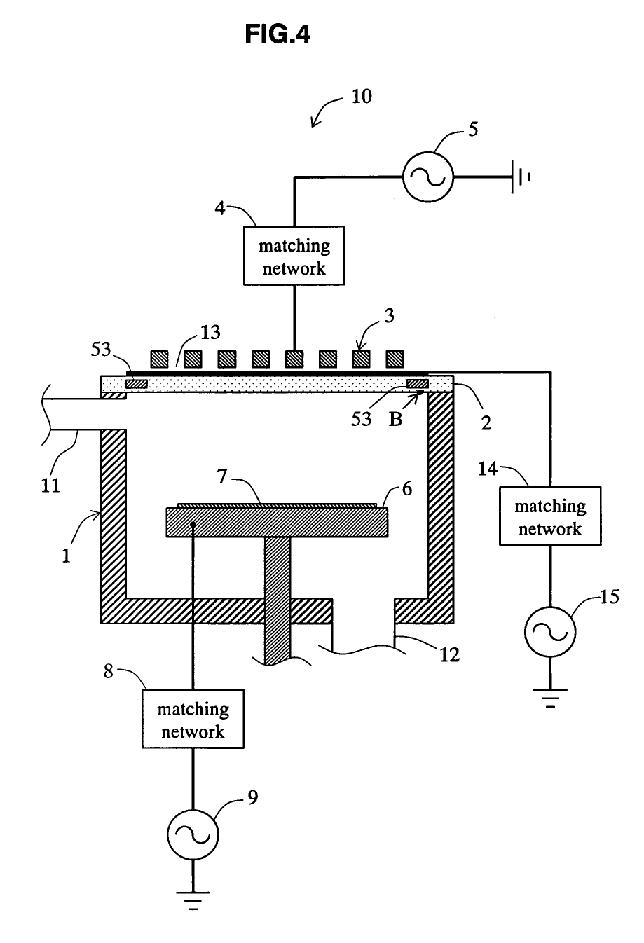

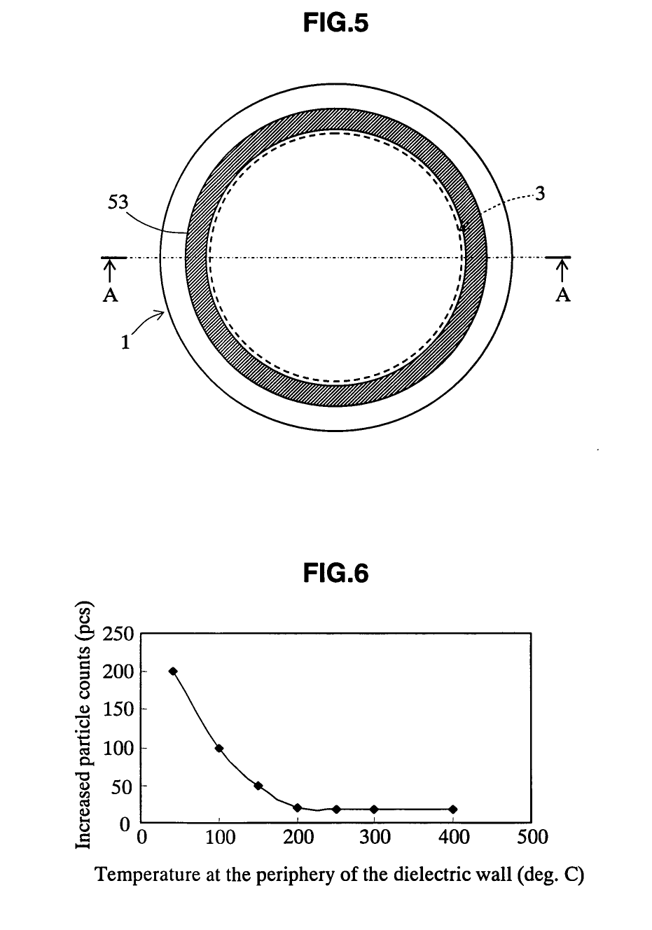

A detailed description of a plasma etching apparatus and plasma etching method relating to a second embodiment of the present invention is provided hereafter, with reference to the drawings. FIG. 4 is a schematic view showing a plasma etching apparatus relating to the present embodiment. Moreover, FIG. 5 is a schematic top view showing the plasma etching apparatus relating to the present embodiment. In addition, FIG. 4 is a cross-sectional view at the A-A line shown in FIG. 5. Furthermore, in FIG. 5, a flat coil is shown only its outer shape by the broken line.

The plasma etching apparatus relating to the present embodiment adopts, in lieu of the lamp 51 of the first embodiment, a heater as the heating unit which heats the periphery of the dielectric wall 2. In other words, as shown in FIG. 4 and FIG. 5, the plasma etching apparatus 10 of the present embodiment is provided with a heater 53 such as an electrical resistance heater and the like in the periphery of the dielectric wall 2. The heater 53 may be arranged on the upper surface (outside of the chamber 1) of the dielectric wall 2. However, in order to effectively increase the temperature on the inner surface side of the chamber 1, the heater 53 is desirably embedded as close as possible to the inner surface of the chamber 1 within the dielectric wall 2. Moreover, the heater 53 is desirably a ring-shape heat generating component in order to make uniform temperature distribution of the periphery of the dielectric wall 2. However, if the construction is capable of increasing the temperature of the periphery of the dielectric wall 2, then it is possible to adopt an arbitrary construction. For example, a plurality of the heaters is arranged at specified intervals along the periphery of the dielectric wall 2 corresponding to the lamps 51 shown in FIG. 2.

In FIG. 6, in the plasma etching apparatus 10 of the above composition, shows increased particle counts in the case of etching an electrode film which has the cross-sectional structure shown in FIG. 11A. In FIG. 6, the horizontal axis corresponds to the temperature at the chamber inner surface side of the periphery of the dielectric wall 2 (arrow B in FIG. 1), and the vertical axis corresponds to the increased particle counts.

Moreover, etching the multilayered film can be performed by introducing a flow rate of 100 sccm of Cl₂ gas, and 250 sccm of O₂ gas as the etching gas, and at the same time, maintaining the pressure inside the chamber 1 at about 2.0 Pa. At this time, the high-frequency power source 5 applies the high-frequency power (at the frequency of 13.56 MHz) of 1500 W to the flat coil 3, the high-frequency power source 9 applies the high-frequency power (at the frequency of 13.56 MHz) of 200 W to the stage 6. In addition, the high-frequency power source 15 applies the high-frequency power (at the frequency: 12.56 MHz) of 300 W to the Faraday shield electrode 13. And then, the temperature of the stage 6 is maintained at about 50 degree C.

As shown in FIG. 6, relative to the fact that the number of increased particle counts is about 200 pcs in the case where heating by the heater 53 is not performed (where the periphery temperature of the dielectric wall is 25 degree C.), the increased particle counts is reduced to 20 or less as the upper limit in the generally fabrication process of semiconductor devices in the case of heating the periphery of the dielectric wall 2 to 200 degree C. or greater by means of the heater 53 heating.

As explained above, according to the present embodiment, in the center of the dielectric wall 2, the adhesion of reaction products can be suppressed by the operation of the Faraday shield electrode 13. And in the periphery of the dielectric wall 2, the adhesion of the reaction products can be suppressed by heating the periphery temperature maintaining at 200 degree C. or greater. Therefore, the adhesion of reaction products can be suppressed across the entire surface of the dielectric wall 2. Owing to this, it is possible to perform the plasma etching process stably without reducing the manufacturing yield.

Furthermore, in the present embodiment, in order to embed a heater 53 within the dielectric wall 2, the heating unit can be arranged in the vicinity of the inner surface of the chamber 1 in comparison with the first embodiment. In other words, even if the temperature retention film 52 is not formed on the chamber inner surface side of the dielectric wall 2 in order to suppress the heat discharging from the dielectric wall 2 in the first embodiment, the inner surface of the periphery of the dielectric wall 2 can be maintained at a high temperature of 200 degree C. or greater.

Since the temperature retention film 52 in the first embodiment is directly exposed to the plasma, over an extended period exfoliation will occur as a result of sputtering of the incident ions. For example, with the etching process under the described conditions, the exfoliation of the temperature retention film 52 will be generated after 70 hours of the processing time. In this case, it is necessary to exchange the dielectric wall 2. Since the plasma etching apparatus cannot be ordinarily operated when accomplishing during such exchange operation, the operating efficiency of the apparatus is reduced. However, with the present embodiment, since it is possible to maintain the temperature of the dielectric wall 2 even if there is no formation of the temperature retention film 52, there is no need to exchange the dielectric wall 2 caused by the exfoliation of the temperature retention film 52. Furthermore, according to the present embodiment, improved operating efficiency of the apparatus can be provided in comparison with the first embodiment.

### Third embodiment

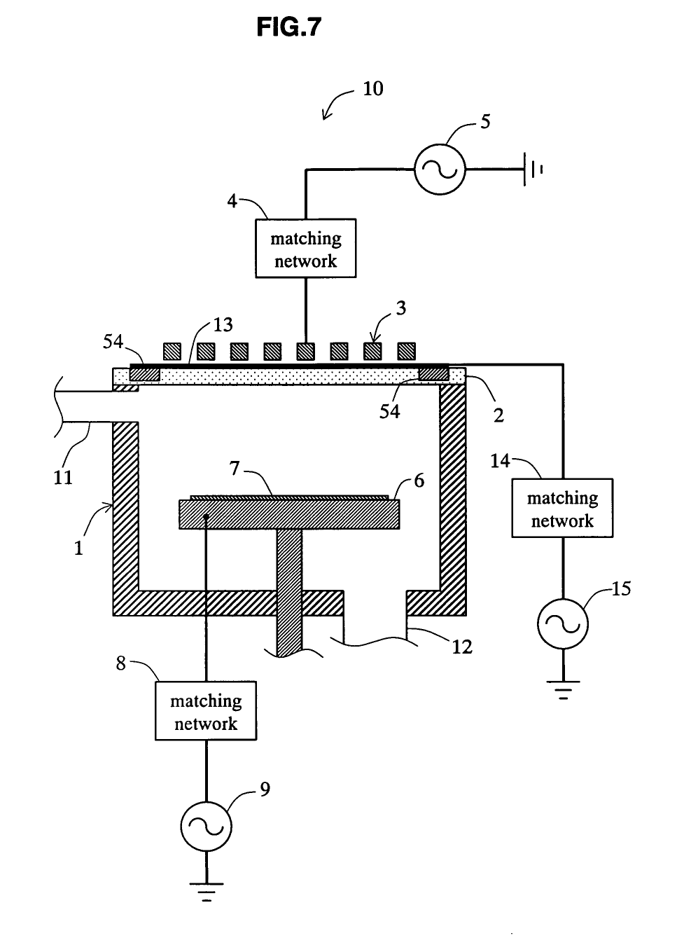

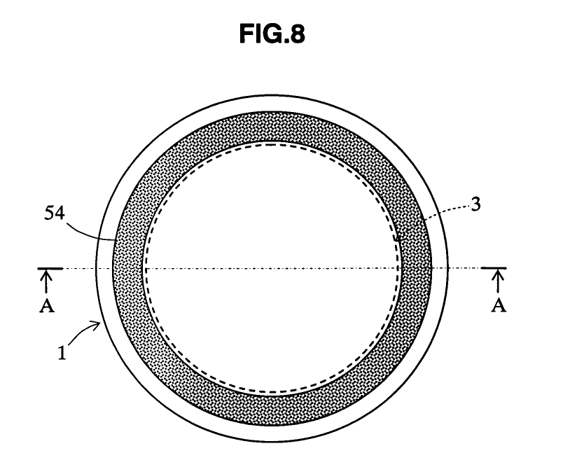

An explanation of the plasma etching apparatus and plasma etching method relating to the third embodiment of the present invention is provided hereafter, with reference to the drawings. FIG. 7 is a schematic view showing the plasma etching apparatus relating to the present embodiment. Moreover, FIG. 8 is a schematic top view showing the plasma etching apparatus relating to the present embodiment. In addition, FIG. 7 is a cross-sectional view at the A-A line shown in FIG. 8. Furthermore, in FIG. 8, a flat coil is shown only its outer shape by the broken line.

The plasma etching apparatus relating to the present embodiment adopts, in lieu of the heater 53 of the second embodiment, a high-frequency power absorber 54 made of absorption material of the high-frequency power as the heating unit. In other words, as shown in FIG. 7 and FIG. 8, the plasma etching apparatus 10 of the present embodiment comprise the dielectric wall 2 of which the periphery is composed of the high-frequency power absorber 54. The quantity of the heat to be generated by the absorber 54 is proportional to the dielectric tangent (tand) of the absorber 54. Owing to this, for example, by adopting material which has a dielectric tangent capable of maintaining the periphery temperature of the dielectric wall 2 at 200 degree C. by the electric power supplied from the high-frequency power sources 5 and 15 through the flat coil 3 and Faraday shield electrode 13, in terms of etching conditions shown in the second embodiment, as the absorber 54, the same effect can be obtained as that of the second embodiment. Moreover, even if material of which the dielectric tangent does not reach the periphery temperature of the dielectric wall 2 at 200 degree C. by the high-frequency power shown as the etching conditions of the second embodiment is adopted as the absorber 54, the same effect as that of the second embodiment can be obtained by increasing the high-frequency power supplied by the high-frequency power sources 5 and 15.

In addition, in the example shown in FIG. 8, in order to make uniform the temperature distribution of the periphery of the dielectric wall 2, the entire periphery is composed of a ring-shaped absorber 54. However, if the composition is such that it is able to increase the periphery temperature of the dielectric wall 2, then it is possible to adopt an arbitrary composition. For example, corresponding to the lamps 51 exemplified in FIG. 2, the composition of multiple regions formed from the absorber 54 can be arranged at specified intervals along the periphery of the dielectric wall 2. Moreover, in FIG. 7, a part of the thickness direction of the dielectric wall 2 is formed from the absorber 54. However, at the time of the etching process, if it is un-etched material, all of the material in the thickness direction may be formed from the absorber 54.

As explained above, according to the present invention, since there is no adhesion of reaction products on the dielectric wall opposing the object to be processed, the generation of particles can be suppressed. Owing to this, even if the etching process forms a fine pattern, high manufacturing yield can be realized. In particularly, with the present invention, even under conditions in which reaction products are generated which have a high boiling point as in the case of etching a metallic film or metallic alloy film containing Pt, Ir, Cu and Al and the like, by means of a halogen-based gas, fine metallic pattern can be formed with high manufacturing yield since the adhesion of reaction products can be suppressed across the entire surface of the dielectric wall.

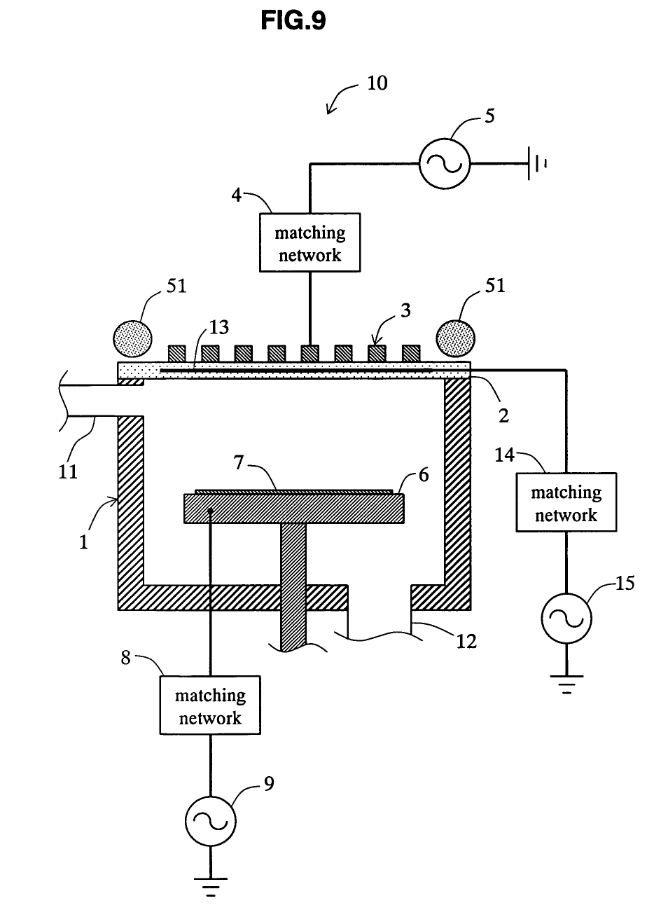

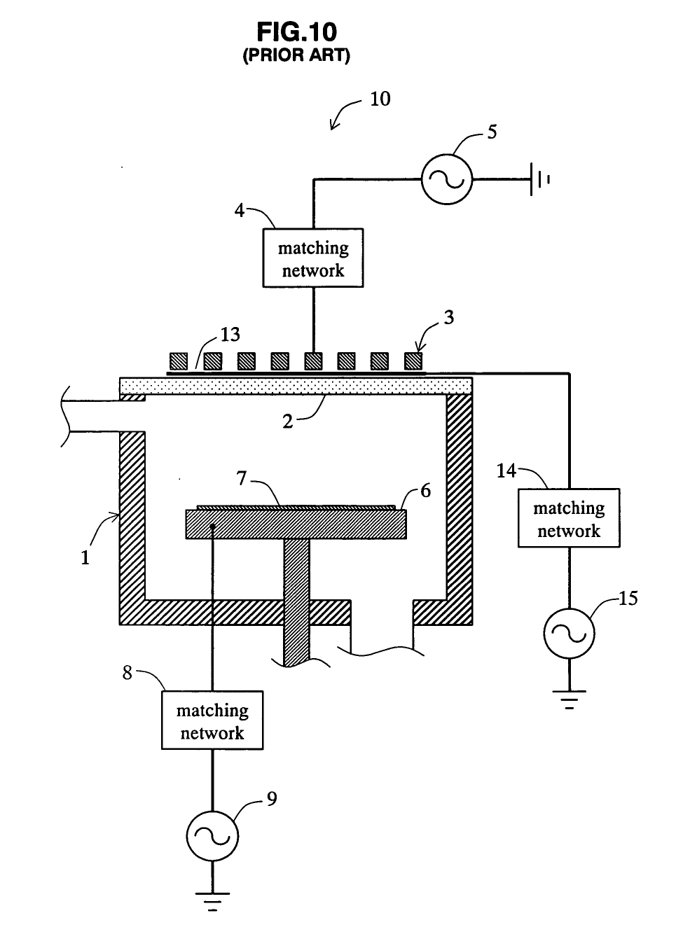

Furthermore, in each of the embodiments, construction in which the Faraday shield electrode 13 is embedded in the dielectric wall 2 is acceptable. For example, by embedding the Faraday shield electrode 13 of the first embodiment shown in FIG. 1 within a dielectric wall 2, such as is shown in FIG. 9, the thickness of the dielectric between the Faraday shield electrode 13 and the plasma created in the chamber 1 can be reduced. According to such construction, the high-frequency power applied in order to suppress the adhesion of the reaction products on the chamber inner surface side of the dielectric wall 2 can be made small in comparison with the composition shown in FIG. 1 since the high-frequency power loss by the dielectric is reduced. In addition, with the this composition, since the heat generated by the lamps 51 accumulates in the Faraday shield electrode 13, it is possible to maintain the periphery temperature of the dielectric wall 2 at a high temperature without providing the temperature retention film 52 shown in FIG. 1.

In addition, the present invention is not restricted to the explained embodiment, and various changes in form and application are possible within parameters completing the effect of the present invention. For example, the present invention may also be appropriately applied to any dry etching apparatus provided with a flat coil corresponding to a dielectric wall, and is further provided with a Faraday shield electrode between the dielectric wall and the flat coil. For example, the shape of the chamber and the like is not limited to the aforementioned shape. In addition, an example is cited above in which the application of the present invention specifically uses the etching process of materials which are difficult to etch, such as Pt and Ir and the like. However, the present invention may also be applied to the etching process of films formed from any materials.

The present invention can be realized with high manufacturing yield in etching process which forms fine patterns, and can be beneficially used in pattern fabrication accomplished by plasma etching.

1. A plasma etching apparatus for performing an etching process on an object to be processed using plasma which has been excited by an induction magnetic field in a chamber, comprising:
a chamber comprising a dielectric wall which transmits an electromagnetic wave at the opposing position to an object to be processed;
a flat coil configured to create the induction magnetic field provided at the exterior of the chamber in response to the dielectric wall;
a plate-shaped electrode configured to function as a Faraday shield provided between the flat coil and the dielectric wall; and,
a heating unit configured to heat a periphery of the dielectric wall.

2. The plasma etching apparatus according to claim 1, wherein the heating unit is composed of a lamp.

3. The plasma etching apparatus according to claim 2, wherein the lamp is movably arranged along the periphery of the dielectric wall.

4. The plasma etching apparatus according to claim 1, wherein the heating unit is composed of an electrical heater.

5. The plasma etching apparatus according to claim 1, wherein the heating unit is composed of an absorber of a high-frequency power.

6. The plasma etching apparatus according to claim 1, wherein a temperature retention film is provided which suppresses the discharge of heat from the dielectric wall on the chamber inner surface side of the dielectric wall.

7. The plasma etching apparatus according to claim 2, wherein a temperature retention film is provided which suppresses the discharge of heat from the dielectric wall on the chamber inner surface side of the dielectric wall.

8. The plasma etching apparatus according to claim 3, wherein a temperature retention film is provided which suppresses the discharge of heat from the dielectric wall on the chamber inner surface side of the dielectric wall.

9. The plasma etching apparatus according to claim 4, wherein a temperature retention film is provided which suppresses the discharge of heat from the dielectric wall on the chamber inner surface side of the dielectric wall.

10. The plasma etching apparatus according to claim 5, wherein a temperature retention film is provided which suppresses the discharge of heat from the dielectric wall on the chamber inner surface side of the dielectric wall.

11. The plasma etching apparatus according to claim 1, wherein the plate-shaped electrode is embedded in the dielectric wall.

12. The plasma etching apparatus according to claim 2, wherein the plate-shaped electrode is embedded in the dielectric wall.

13. The plasma etching apparatus according to claim 3, wherein the plate-shaped electrode is embedded in the dielectric wall.

14. The plasma etching apparatus according to claim 4, wherein the plate-shaped electrode is embedded in the dielectric wall.

15. The plasma etching apparatus according to claim 5, wherein the plate-shaped electrode is embedded in the dielectric wall.

16. A plasma etching method for performing an etching process on an object to be processed in a chamber using plasma excited by an induction dialectic magnetic field which is formed by a flat coil provided at the exterior of the chamber in response to the dielectric wall which transmits an electromagnetic wave at the opposing position to the object to be processed; comprising the steps of:
creating a plasma in the chamber;
heating the periphery of the dielectric wall during an etching process; and wherein,
the etching process of the object to be processed is accomplished under a conditions in which there is no etching of the dielectric wall by ions incidental to the dielectric wall, from the plasma, by means of applying electric potential to the plate-shaped electrode arranged between the dielectric wall and the flat coil.

17. The plasma etching method according to claim 16, wherein the object to be processed includes at least one material selected from platinum, iridium, copper or aluminum.
